(19) United States
(12) Patent Application Publication
(10) Pub. No.: US 2016/0273126 A1
(43) Pub. Date: Sep. 22, 2016

(54) METHOD FOR PRODUCING SiC SINGLE CRYSTAL

(71) Applicant: NIPPON STEEL & SUMITOMO METAL CORPORATION, Tokyo (JP)

(72) Inventors: Kazuhiko Kusunoki, Nishinomiya-shi, Hyogo (JP); Kazuhito Kamei, Kitakyushu-shi, Fukuoka (JP)

(21) Appl. No.: 15/029,379

(22) PCT Filed: Nov. 12, 2014
(86) PCT No.: PCT/JP2014/005671

§ 371 Date: Apr. 14, 2016

(30) Foreign Application Priority Data
Nov. 12, 2013 (JP) 2013-234281

(51) Int. Cl. C30B 19/04; C30B 29/36; C30B 19/12; C30B 9/06; C30B 19/06

(52) U.S. Cl. CPC C30B 19/04; C30B 9/06; C30B 19/062; C30B 19/067; C30B 19/12; C30B 29/36

(57) ABSTRACT

Provided is a method for producing a SiC single crystal by a solution growth method, the production method being capable of growing a SiC single crystal doped with Al even when a graphite crucible is used. The production method according to an embodiment of the present invention includes the steps of: forming a Si—C solution in a graphite crucible, and bringing a SiC seed crystal into contact with the Si—C solution and growing the SiC single crystal on the SiC seed crystal. The Si—C solution contains Si, Al, and Cu in a range satisfying Formula (1), with the balance of the Si—C solution being C and impurities. In Formula (1), [Si], [Al], and [Cu] represent contents of Si, Al and Cu expressed by mol %, respectively.

0.03<[Cu]/([Si]+[Al]+[Cu])≦0.5 (1)

### TECHNICAL FIELD

The present invention relates to a method for producing a SiC single crystal, and more particularly to a method for producing a SiC single crystal containing Al as a dopant by a solution growth method.

### BACKGROUND ART

Examples of the method for producing a SiC single crystal include a sublimation method and a solution growth method. In a sublimation method, a raw material is transformed into a gas phase and supplied onto a seed crystal in a reaction vessel, thereby growing a single crystal.

In a solution growth method, a seed crystal is brought into contact with a Si—C solution, thereby causing a SiC single crystal to grow on the seed crystal. The Si—C solution as used herein refers to a solution in which C (carbon) is dissolved into a melt of Si or Si alloy. In a solution growth method, typically, a graphite crucible is used as a vessel for accommodating the Si—C solution. When a raw material containing Si is melt in a graphite crucible to form a melt, C dissolves into the melt from the graphite crucible. As a result, the melt becomes a Si—C solution.

### CITATION LIST

### Non Patent Literature

Non Patent Literature 1: C. Jacquier and five others, Journal of Materials Science, 2002, vol. 37, p. 3299-3306.
Non Patent Literature 2: C. Jacquier and five others, Journal of Crystal Growth, 254, 2003, p. 123-130.

### SUMMARY OF INVENTION

When a SiC single crystal with p-type conductivity is produced, typically, Al (aluminum) is doped as a dopant. The production of a SiC single crystal by a sublimation method is typically conducted under a reduced-pressure atmosphere, and a graphite crucible is used as the reaction vessel. Under a reduced-pressure atmosphere, Al is likely to evaporate. Since the graphite crucible is porous, evaporated Al transmits through the graphite crucible. For this reason, producing a SiC single crystal doped with Al by a sublimation method will lead to leakage of Al, which is the dopant, from the reaction vessel (graphite crucible). Therefore, it is difficult to produce a low resistance SiC single crystal highly doped with Al by a sublimation method. On the other hand, in a solution growth method, a SiC single crystal highly doped with Al can be produced by using a Si—C solution containing Al.

However, in a solution growth method, Al contained in the Si—C solution will severely react with graphite (see above-described Non Patent Literature 1). Therefore, when a Si—C solution containing Al is formed and retained in a graphite crucible, the graphite crucible may be broken in a short period of time due to reaction with Al (see above-described Non Patent Literature 2). For this reason, in a solution growth method, it has been difficult to produce a SiC single crystal doped with Al and having a large thickness.

It is an object of the present invention to provide a method for producing a SiC single crystal by a solution growth method, the production method being capable of growing a SiC single crystal doped with Al even when a graphite crucible is used.

A method for producing a SiC single crystal according to an embodiment of the present invention is a method for producing a SiC single crystal by a solution growth method. The production method includes the steps of: forming a Si—C solution containing Si, Al, and Cu in a range satisfying below-described Formula (1), with the balance being C and impurities, in a graphite crucible; and bringing a SiC seed crystal into contact with the Si—C solution and growing the SiC single crystal on the SiC seed crystal:

0.03<[Cu]/([Si]+[Al]+[Cu])≦0.5 (1)

where, [Si], [Al], and [Cu] represent contents of Si, Al and Cu expressed by mol %, respectively.

A method for producing a SiC single crystal according to another embodiment of the present invention is a method for producing a SiC single crystal by a solution growth method. The production method includes the steps of: forming a Si—C solution containing Si, Al, Cu, and M (M is one or more elements selected from the group consisting of Ti, Mn, Cr, Co, Ni, V, Fe, Dy, Nd, Tb, Ce, Pr, and Sc) in a range satisfying below-described Formula (2), with the balance being C and impurities, in a graphite crucible; and bringing a SiC seed crystal into contact with the Si—C solution and growing the SiC single crystal on the SiC seed crystal:

0.03<[Cu]/([Si]+[Al]+[Cu]+[M])<0.5 (2)

where, [M] represents a total of contents in mol % of one or more elements selected from the group consisting of Ti, Mn, Cr, Co, Ni, V, Fe, Dy, Nd, Tb, Ce, Pr, and Sc.

In the method for producing a SiC single crystal according to embodiments of the present invention, it is possible to grow a SiC single crystal doped with Al even when a graphite crucible is used.

### BRIEF DESCRIPTION OF DRAWINGS

FIG. 1 is a schematic configuration diagram of a production apparatus which can be used for performing a method for producing a SiC single crystal according to an embodiment of the present invention.

FIG. 2 is a diagram to show relationship between Al concentration of a Si—C solution and an Al concentration of a SiC single crystal obtained from the Si—C solution.

### DESCRIPTION OF EMBODIMENTS

In a method for producing a SiC single crystal according to an embodiment of the present invention, a SiC single crystal is grown by a solution growth method. The above-described production method includes the steps of: forming a Si—C solution containing Si (silicon), Al (aluminum), and Cu (copper) in a range satisfying below-described Formula (1), with the balance being C (carbon) and impurities, in a graphite crucible; and bringing a SiC seed crystal into contact with the Si—C solution and growing the SiC single crystal on the SiC seed crystal:

0.03<[Cu]/([Si]+[Al]+[Cu])≦0.5 (1)

where, [Si], [Al], and [Cu] are substituted by contents of Si, Al and Cu expressed by mol %, respectively.

In the production method according to the present embodiment, the Si—C solution contains Cu in an amount to satisfy Formula (1). This Si—C solution suppresses reaction between Al and graphite, compared with a Si—C solution that contains Al and substantially no Cu. As a result, when this Si—C solution is accommodated in a graphite crucible, excessive reaction between Al in the Si—C solution and the graphite crucible is suppressed. Therefore, breakage of graphite crucible due to reaction with Al is less likely to occur. Thus, in the production method of the present embodiment, since damage of the graphite crucible during crystal growth is suppressed, it is possible to grow a SiC single crystal doped with Al.

When the Cu content (mol %) in the Si—C solution is excessively low, the effect of suppressing the reaction between Al in the Si—C solution and graphite cannot be sufficiently achieved. Now, it is defined that F1=[Cu]/([Si]+[Al]+[Cu]), where, [Cu], [Si], and [Al] are respectively contents (mol %) of each element in the Si—C solution. When F1 is not more than 0.03, the Cu content in the Si—C solution is excessively low. For that reason, the graphite crucible may severely react with Al during crystal growth, thus causing breakage of the graphite crucible. When F1 is more than 0.03, the Cu content in the Si—C solution is sufficiently high. For that reason, the graphite crucible is less likely to be broken during growth of SiC single crystal, and it is possible to grow a SiC single crystal doped with Al. The lower limit of F1 is preferably 0.05, and more preferably 0.1.

On the other hand, when the Cu content of the Si—C solution is excessively high, specifically, when F1 is more than 0.5, the amount of dissolved carbon in the Si—C solution becomes insufficient. As a result, the growth speed of SiC single crystal will be markedly reduced. Moreover, Cu is an element having a high vapor pressure. When F1 is more than 0.5, evaporation of Cu from the Si—C solution becomes significant, and the liquid level of the Si—C solution will be markedly reduced. Since decrease in the liquid level leads to decrease in the temperature at the crystal growth interface, the degree of supersaturation of Si—C solution increases. As a result, it becomes difficult to maintain a stable crystal growth. When F1 is not more than 0.5, decrease in the growth speed of SiC single crystal is suppressed, and further a stable crystal growth can be maintained. The upper limit of F1 is preferably 0.4, and more preferably 0.3.

Al contained in the Si—C solution is taken into a SiC single crystal which grows on the SiC seed crystal. As a result, a SiC single crystal doped with Al (SiC single crystal with p-type conductivity) is obtained. On the other hand, as a result of performing SIMS analysis, it was found that Cu contained in the Si—C solution is scarcely taken into the SiC single crystal. Therefore, the Cu content causes substantially no variation in properties of SiC single crystal.

The Si—C solution of the present embodiment may further contain one or more elements selected from the group consisting of Ti, Mn, Cr, Co, Ni, V, Fe, Dy, Nd, Tb, Ce, Pr, and Sc. Any of Ti, Mn, Cr, Co, Ni, V, Fe, Dy, Nd, Tb, Ce, Pr, and Sc increases the amount of dissolved carbon of Si—C solution. By using a Si—C solution having a large amount of dissolved carbon, it is possible to increase the growth speed of SiC single crystal.

When the Si—C solution contains any of the above described optional elements, the Si—C solution satisfies the following Formula (2) in place of Formula (1):

0.03<[Cu]/([Si]+[Al]+[Cu]+[M])<0.5 (2)

where [M] in Formula (2) is substituted by contents (mol %) of one or more elements selected from the group consisting of Ti, Mn, Cr, Co, Ni, V, Fe, Dy, Nd, Tb, Ce, Pr, and Sc. When a plurality of the above-described optional elements are contained in the Si—C solution, the total of contents (mol %) of contained optional elements is substituted into [M].

Now, it is defined that F2=[Cu]/([Si]+[Al]+[Cu]+[M]). When F2 is more than 0.03, the Cu content in the Si—C solution is sufficiently high. For that reason, the graphite crucible is less likely to be broken during growth of SiC single crystal. The lower limit of F2 is preferably 0.05, and more preferably 0.1.

On the other hand, when F2 is less than 0.5, decrease in the growth speed of SiC single crystal will be suppressed, and evaporation of Cu will also be suppressed. The upper limit of F2 is preferably 0.4, and more preferably 0.3.

When a Si—C solution containing substantially no Cu is used, and in order to suppress the reaction between Al in the Si—C solution and the graphite crucible to cause the SiC single crystal to grow, it is necessary, for example, to make the crystal growth temperature less than 1200° C. (see above-described Non Patent Literature 2). In this case, the growth speed of SiC single crystal is low.

On the other hand, in the production method of the present embodiment, since the Si—C solution satisfies Formula (1) or Formula (2), there is no need of decreasing the temperature of the Si—C solution. Specifically, in the production method of the present embodiment, the crystal growth temperature is preferably more than 1500° C. The “crystal growth temperature” as used herein is defined as a “temperature at the interface between the Si—C solution and the seed crystal (crystal growth plane) during crystal growth”. In the production method of the present embodiment, the crystal growth temperature is measured as follows. In the production of a SiC single crystal, a tubular seed shaft having a bottom portion is used. A SiC seed crystal is bonded to a lower end surface of the bottom portion of the seed shaft, and crystal growth is allowed. At this moment, an optical thermometer is disposed within the seed shaft to measure the temperature of the bottom portion of the seed shaft. The value measured by the optical thermometer is assumed to be the crystal growth temperature (° C.).

In a Si—C solution, a maximum temperature of its portion that is in contact with the graphite crucible is, typically, 5 to 50° C. higher than the crystal growth temperature. In the production method of the present embodiment, even when the crystal growth temperature is higher than 1500° C., the graphite crucible is less likely to be broken. Further, by making the crystal growth temperature higher than 1500° C., it is possible to increase the growth speed of SiC single crystal. The lower limit of the crystal growth temperature is more preferably 1600° C., further preferably 1700° C. and further preferably 1770° C.

When the crystal growth temperature is more than 2100° C., Si—C solution markedly evaporates. Therefore, the upper limit of the crystal growth temperature is preferably 2100° C. The upper limit of the crystal growth temperature is more preferably 2050° C., further preferably 2000° C., and further preferably 1950° C.

In the production method of a SiC single crystal of the present embodiment, it is preferable that the Si—C solution further satisfies Formula (3):

0.14≦[Al]/[Si]≦2 (3)

where, [Al] and [Si] are respectively the Al content (mol %) and the Si content (mol %) in the Si—C solution.

Now, it is defined that F3=[Al]/[Si]. When F3 is not less than 0.14, it is possible to make the amount of doped Al of the SiC single crystal not less than 3×10¹⁹ atoms/cm³. In this case, the specific resistance of the SiC single crystal will become sufficiently low. The lower limit of F3 is more preferably 0.2, and further preferably 0.3.

On the other hand, when F3 is more than 2, SiC may not be crystalized from the Si—C solution. When F3 is not more than 2, SiC is likely to be stably crystalized. Therefore, the upper limit of F3 is preferably 2. The upper limit of F3 is more preferably 1.5, and further preferably 1.

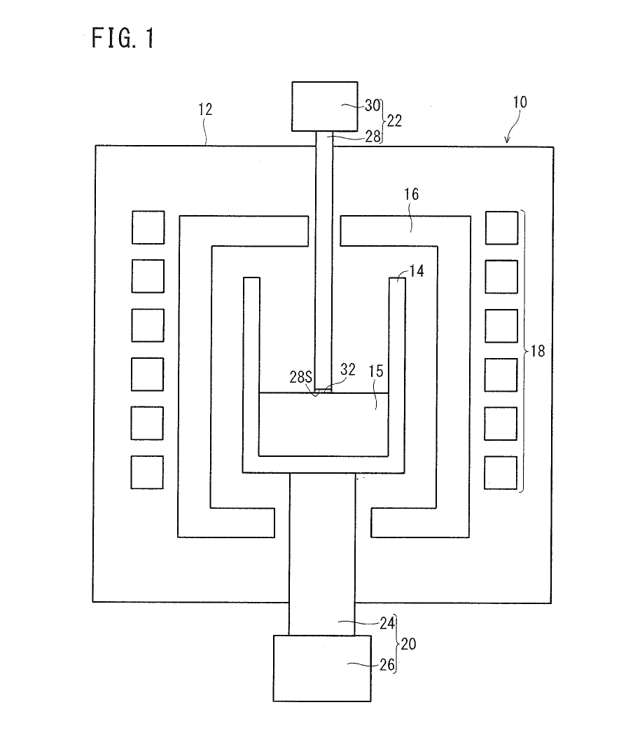

Next, referring to the drawings, a production method of a SiC single crystal relating to the present embodiment will be specifically described. FIG. 1 is a schematic configuration diagram of a production apparatus of a SiC single crystal, which may be used for the production method of a SiC single crystal of the present embodiment.

Referring to FIG. 1, the production includes a chamber 12, a graphite crucible 14, a heat insulation member 16, a heating device 18, a rotary device 20, and a lifting device 22.

The graphite crucible 14 is accommodated in the chamber 12. The graphite crucible 14 accommodates thereinside raw material for Si—C solution. The graphite crucible 14 contains graphite. The graphite crucible 14 is preferably made of graphite. The heat insulation member 16 is made up of heat insulation material. The heat insulation member 16 surrounds the graphite crucible 14.

The heating device 18 surrounds the side wall of the heat insulation member 16. The heating device 18 is, for example, a high-frequency coil and inductively heats the graphite crucible 14. The raw material is melted in the graphite crucible 14, and a Si—C solution 15 is formed. The Si—C solution 15 serves as the raw material for the SiC single crystal.

The Si—C solution 15 contains, as described above, C, Al, and Cu, with the balance being Si and impurities, and satisfies above-described Formula (1).

The Si—C solution 15 may further contain one or more elements, as optional elements, selected from the group consisting of Ti, Mn, Cr, Co, Ni, V, Fe, Dy, Nd, Tb, Ce, Pr, and Sc. When the optional elements are contained, the Si—C solution 15 satisfies above-described Formula (2).

The raw material for the Si—C solution 15 is for example a mixture of Si and other metal elements (Al and Cu (and one or more elements selected from the group consisting of Ti, Mn, Cr, Co, Ni, V, Fe, Dy, Nd, Tb, Ce, Pr, and Sc)). The raw material is heated to obtain a melt, and carbon (C) dissolves into the melt, thereby forming the Si—C solution 15. The graphite crucible 14 works as a carbon source to the Si—C solution 15. By heating the graphite crucible 14, it is possible to maintain the Si—C solution 15 at a crystal growth temperature.

The rotary device 20 includes a rotary shaft 24 and a driving source 26. An upper end of the rotary shaft 24 is located in the heat insulation member 16. The graphite crucible 14 is disposed on the upper end of the rotary shaft 24. A lower end of the rotary shaft 24 is located outside the chamber 12. The driving source 26 is disposed below the chamber 12. The driving source 26 is connected to the rotary shaft 24. The driving source 26 rotates the rotary shaft 24 around its center axis. And this causes the graphite crucible 14 (Si—C solution 15) to rotate.

The lift device 22 includes a bar-like seed shaft 28 and a driving source 30. The seed shaft 28 is predominantly made of, for example, graphite. An upper end of the seed shaft 28 is located outside the chamber 12. A SiC seed crystal 32 is attached to a lower end surface 28S of the seed shaft 28.

The SiC seed crystal 32 is made up of a SiC single crystal. Preferably, the SiC seed crystal 32 has the same crystal structure as that of the SiC single crystal to be produced. For example, when a SiC single crystal with 4H polymorph is produced, a SiC seed crystal 32 with 4H polymorph is preferably used. The SiC seed crystal 32 is plate-shaped and is attached to the lower end surface 28S.

The driving source 30 is disposed above the chamber 12. The driving source 30 is connected to the seed shaft 28. The driving source 30 makes the seed shaft 28 move up and down. This makes it possible to bring the SiC seed crystal 32 attached to the lower end surface 28S of the seed shaft 28 into contact with the liquid surface of the Si—C solution 15 accommodated in the graphite crucible 14. The driving source 30 rotates the seed shaft 28 around the center axis thereof. The driving source 30 further rotates the seed shaft 28 around the center axis thereof. In this case, the SiC seed crystal 32 attached to the lower end surface 28S rotates. The rotational direction of the seed shaft 28 may be in the same direction as or an opposite direction to the rotational direction of the graphite crucible 14.

The method for producing a SiC single crystal by using the above described production apparatus 10 will be described. First of all, the above described Si—C solution 15 is formed in the graphite crucible 14. First, raw material for the Si—C solution 15 is accommodated in the graphite crucible 14. The graphite crucible 14 in which the raw material is accommodated is accommodated in the chamber 12. To be specific, the graphite crucible 14 is disposed on the rotary shaft 24.

After the graphite crucible 14 is accommodated in the chamber 12, the atmosphere in the chamber 12 is replaced with an inert gas such as Ar (argon) gas. Thereafter, the graphite crucible 14 is heated by the heating device 18. As a result of heating, the raw material in the graphite crucible 14 is melted to foini a melt. Further, as a result of heating, carbon dissolves into the melt from the graphite crucible 14. As a result, the Si—C solution 15 is formed in the graphite crucible 14. Carbon of the graphite crucible 14 continues to dissolve into the Si—C solution 15, and the carbon concentration of the Si—C solution 15 approaches a saturated concentration.

The formed Si—C solution 15 contains C, Al, and Cu with the balance being Si and impurities. The Si—C solution further satisfies Formula (1). When the Si—C solution 15 further contains as optional elements one or more elements selected from the group consisting of Ti, Mn, Cr, Co, Ni, V, Fe, Dy, Nd, Tb, Ce, Pr, and Sc, the Si—C solution 15 satisfies Formula (2) instead of Formula (1).

In the Si—C solution 15, the ratio of [Si], [Al], and [Cu], and the ratio of [Si], [Al], [Cu], and [M] can be regarded as the same as those of the raw materials before melting. Whichever composition the Si—C solution 15 has, it is preferable that the Si—C solution 15 satisfies Formula (3).

Next, the SiC seed crystal 32 is brought into contact with the Si—C solution 15 to cause a SiC single crystal to grow on the SiC seed crystal 32. To be specific, after the Si—C solution 15 is formed, the seed shaft 28 is moved downward by the driving source 30. Then, the SiC seed crystal 32 attached to the lower end surface 28S of the seed shaft 28 is brought into contact with the Si—C solution 15 in the graphite crucible 14.

After the SiC seed crystal 32 is brought into contact with the Si—C solution 15, a SiC single crystal is grown on the SiC seed crystal 32. To be specific, a vicinity region neighboring the SiC seed crystal 32 in the Si—C solution 15 is supercooled such that the SiC in the vicinity region becomes oversaturated. As a result, a SiC single crystal is grown on the SiC seed crystal 32. The method for supercooling the vicinity region neighboring the seed crystal 32 in the Si—C solution 15 is not particularly limited. For example, the heating device 18 may be controlled such that the temperature of the vicinity region neighboring the seed crystal 32 in the Si—C solution 15 is kept lower than the temperature of the remaining region.

The crystal growth temperature may be higher than, for example, 1500° C. In the Si—C solution 15 accommodated in the graphite crucible 14, the maximum temperature of a portion in contact with the graphite crucible 14 is usually 5 to 50° C. higher than the crystal growth temperature. Even when the Si—C solution 15 of such a high temperature is in contact with the graphite crucible 14, the reaction between the Si—C solution 15 and the graphite crucible 14 is suppressed as a result of the Si—C solution 15 satisfying Formula (1) or Formula (2). Therefore, the graphite crucible 14 is less likely to be broken.

With the vicinity region neighboring the seed crystal 32 in the Si—C solution 15 being kept oversaturated with SiC, the SiC seed crystal and the Si—C solution 15 (graphite crucible 14) are rotated. Rotating the seed shaft 28 causes the seed crystal 32 to rotate. Rotating the rotary shaft 24 causes the graphite crucible 14 to rotate. The rotational direction of the seed crystal 32 may be opposite to, or the same as, the rotational direction of the graphite crucible 14. Moreover, the rotation speed may be constant, or varied. The seed shaft 28 may be made to gradually move up while being rotated by the driving source 30. The seed shaft 28 may be rotated without being moved up, or may be neither moved up, nor rotated.

After the end of crystal growth, the SiC single crystal is detached from the Si—C solution 15, and the temperature of the graphite crucible 14 is lowered to the room temperature.

Since the Si—C solution 15 satisfies Formula (1) or Formula (2), its reaction with graphite is suppressed. For that reason, when the seed shaft 28 is made up of graphite in the above described production method, even if the Si—C solution 15 comes into contact with the seed shaft 28, the seed shaft 28 is less likely to be broken.

As a result of the reaction between the Si—C solution 15 and the graphite crucible 14 being suppressed, it becomes possible to increase not only the time for crystal growth, but also the time for forming Si—C solution 15 by causing C to dissolve into the melt, and the time for the Si—C solution 15 to solidify since the temperature of the graphite crucible 14 is started to be lowered. As a result, for example, when the Si—C solution 15 is foamed by making carbon source in the form of a block, a bar, a granule, a powder, or the like to dissolve into the melt, it is possible to extend a melting time, thus allowing the carbon source to be dissolved completely. Moreover, it is also possible to gradually cool the produced single crystal after the end of crystal growth. For that reason, it is possible to avoid breakage of the single crystal due to thermal shock.

### EXAMPLES

Si—C solutions having various compositions were formed and SiC single crystals were grown by a solution growth method using a graphite crucible.

[Test Method]

Si—C solutions of Test Nos. 1 to 18 shown in Table 1 were produced in the graphite crucible. For each Test No., a graphite crucible having the same shape was used.

TABLE 1

| | Composition | | | | | | | | |
|---|---|---|---|---|---|---|---|---|---|
| | (mol %) of Si—C | | | | | | | | |
| Test | solution | | | | | | | Solution | Graphite |
| No. | Si | Al | Cu | Ti | F1 | F2 | F3 | temperature | crucible |
| 1 | 70 | 10 | 20 | 0 | 0.2 | — | 0.14 | 1770 | E |
| 2 | 70 | 10 | 20 | 0 | 0.2 | — | 0.14 | 1950 | E |
| 3 | 50 | 30 | 20 | 0 | 0.2 | — | 0.60 | 1770 | E |
| 4 | 50 | 40 | 10 | 0 | 0.1 | — | 0.80 | 1770 | E |
| 5 | 50 | 40 | 10 | 0 | 0.1 | — | 0.80 | 1950 | E |
| 6 | 62 | 18 | 10 | 10 | — | 0.1 | 0.29 | 1770 | E |
| 7 | 65 | 20 | 10 | 5 | — | 0.1 | 0.31 | 1940 | E |
| 8 | 40 | 30 | 20 | 10 | — | 0.2 | 0.75 | 1940 | E |
| 9 | 50 | 40 | 10 | 0 | 0.1 | — | 0.80 | 1770 | E |
| 10 | 50 | 30 | 20 | 0 | 0.2 | — | 0.60 | 1770 | E |
| 11 | 50 | 30 | 20 | 0 | 0.2 | — | 0.60 | 1600 | E |
| 12 | 40 | 10 | 50 | 0 | 0.5 | — | 0.25 | 1770 | E |
| 13 | 40 | 20 | 40 | 0 | 0.4 | — | 0.50 | 1770 | E |
| 14 | 70 | 25 | 5 | 0 | 0.05 | — | 0.36 | 1770 | E |
| 15 | 70 | 27 | 3 | 0 | 0.03 | — | 0.39 | 1770 | NA |
| 16 | 75 | 4 | 0 | 21 | — | 0 | 0.05 | 1500 | NA |
| 17 | 72 | 8 | 0 | 20 | — | 0 | 0.11 | 1700 | NA |
| 18 | 70 | 30 | 0 | 0 | 0 | — | 0.43 | 1400 | NA |

Meanings of symbols in the column of “suppression of graphite crucible breakage” are as follows:
E: Graphite crucible was not broken while Si—C solution was accommodated.
NA: Graphite crucible was broken while Si—C solution was accommodated.

A SiC seed crystal was brought into contact with a Si—C solution of each Test No. to grow a SiC single crystal on the SiC seed crystal. The crystal growth temperatures were as shown in Table 1. The time during which the Si—C solution was in contact with the graphite crucible was about 7 to 9 hours including the time for crystal growth.

Heating of the graphite crucible was performed by a high-frequency coil. The amount of current flowing in the high-frequency coil was monitored while the graphite crucible was heated. When the magnitude of this current significantly changed, it was judged that breakage (for example, cracking) of the graphite crucible occurred. When the graphite crucible is broken and the Si—C solution is leaked from the graphite crucible, the volume of an object to be heated by high-frequency induction decreases. For that reason, the magnitude of the current flowing through the high-frequency coil significantly changes. Thus, monitoring change in the current of the high-frequency coil will make it possible to confirm the occurrence or non-occurrence of breakage of the graphite crucible.

After the end of crystal growth, the SiC single crystal was separated from the Si—C solution, ending the heating of the graphite crucible. However, when it was judged that breakage of the graphite crucible had occurred, immediately thereafter, heating of the graphite crucible was ended.

[Test Results]

All of the Si—C solutions used in Test Nos. 1 to 14 contained Cu, and satisfied above-described Formula (1) or Formula (2). To be specific, the Si—C solutions of Test Nos. 2 to 5, and 9 to 14 satisfied Formula (1). The Si—C solutions of Test Nos. 6 to 8 contained Ti, which was an optional element, and satisfied Formula (2). As a result, no breakage of the graphite crucible was confirmed in Test Nos. 1 to 14 even when the crystal growth temperature was higher than 1500° C. In particular, in Test No. 5, although the Si—C solution was in contact with the graphite crucible in an extremely severe condition that the Al content of the Si—C solution was 40% and the crystal growth temperature of the Si—C solution was 1950° C., breakage of the graphite crucible was suppressed.

On the other hand, in Test No. 15, F1 was 0.03 and Formula (1) was not satisfied. As a result, breakage of the graphite crucible was confirmed. The Si—C solutions of Test Nos. 16 to 18 did not contain Cu. As a result, breakage of the graphite crucible was confirmed.

[Relationship Between Al Concentration of Si—C Solution and Al Concentration of SiC Single Crystal]

For Test Nos. 1, 5, and 10, the relationship between the Al concentration of the Si—C solution and the Al concentration of the SiC single crystal produced by using the relevant Si—C solution was investigated. The Al concentrations of the Si—C solutions of Test Nos. 1, 5, and 10 were 5.77×10²¹ atoms/cm³, 2.23×10²² atoms/cm³, and 1.72×10²² atoms/cm³, respectively. Al concentrations were measured for obtained SiC single crystals by SIMS (Secondary Ion Mass Spectrometry).

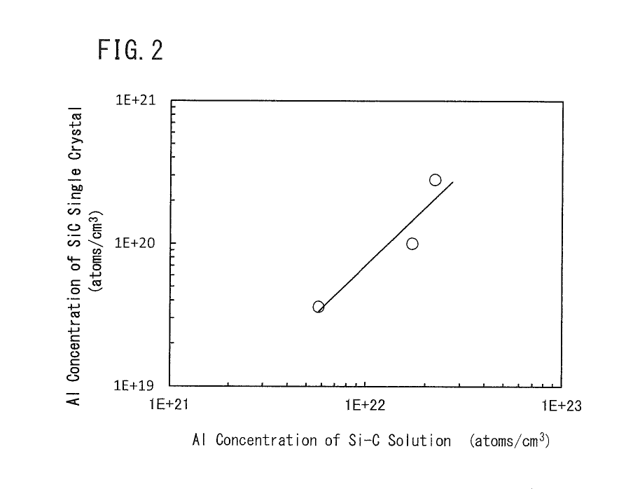

FIG. 2 shows the relationship between the Al concentration of the Si—C solution and the Al concentration of the SiC single crystal obtained from the relevant Si—C solution. As shown in FIG. 2, as the Al concentration of the Si—C solution increased, the Al concentration of the SiC single crystal increased. Therefore, by controlling the Al concentration of the Si—C solution, it was possible to control the Al concentration of the SiC single crystal, and thus the specific resistance of the SiC single crystal.

F3 of the Si—C solution of Test No. 1 was 0.14 (10/70). Therefore, when F3 was not less than 0.14, it was possible to make the amount of doped Al of the SiC single crystal not less than 3×10¹⁹ atoms/cm³.

### REFERENCE SIGNS LIST

14: Graphite crucible, 15: Si—C solution, 32: SiC seed crystal

1. A method for producing a SiC single crystal by a solution growth method, the method comprising the steps of:
forming a Si—C solution containing Si, Al, and Cu in a range satisfying below-described Formula (1), with the balance being C and impurities, in a graphite crucible; and
bringing a SiC seed crystal into contact with the Si—C solution and growing the SiC single crystal on the SiC seed crystal:
0.03<[Cu]/([Si]+[Al]+[Cu])≦0.5 (1)
where, [Si], [Al], and [Cu] represent contents of Si, Al and Cu expressed by mol %, respectively.

2. A method for producing a SiC single crystal by a solution growth method, the method comprising the steps of:
forming a Si—C solution containing Si, Al, Cu, and M (M is one or more elements selected from the group consisting of Ti, Mn, Cr, Co, Ni, V, Fe, Dy, Nd, Tb, Ce, Pr, and Sc) in a range satisfying below-described Formula (2), with the balance being C and impurities, in a graphite crucible; and
bringing a SiC seed crystal into contact with the Si—C solution and growing the SiC single crystal on the SiC seed crystal:
0.03<[Cu]/([Si]+[Al]+[Cu]+[M])<0.5 (2)
where, [M] represents a total of contents in mol % of one or more elements selected from the group consisting of Ti, Mn, Cr, Co, Ni, V, Fe, Dy, Nd, Tb, Ce, Pr, and Sc.

3. The method for producing a SiC single crystal according to claim 1, wherein
crystal growth temperature is higher than 1500° C. in the Si—C solution.

4. The method for producing a SiC single crystal according to claim 2, wherein crystal growth temperature is higher than 1500° C. in the Si—C solution.

5. The method for producing a SiC single crystal according to claim 1, wherein
contents of Al and Si in the Si—C solution satisfy below-described Formula (3):
0.14≦[Al]/[Si]≦2 (3)

6. The method for producing a SiC single crystal according to claim 2, wherein
contents of Al and Si in the Si—C solution satisfy below-described Formula (3):
0.14≦[Al]/[Si]≦2 (3)

7. The method for producing a SiC single crystal according to claim 3, wherein
contents of Al and Si in the Si—C solution satisfy below-described Formula (3):
0.14≦[Al]/[Si]≦2 (3)

8. The method for producing a SiC single crystal according to claim 4, wherein
contents of Al and Si in the Si—C solution satisfy below-described Formula (3):
0.14≦[Al]/[Si]≦2 (3)
